(19) United States
(12) Patent Application Publication
(10) Pub. No.: US 2019/0181093 A1
(43) Pub. Date: Jun. 13, 2019

(54) ACTIVE PACKAGE SUBSTRATE HAVING EMBEDDED INTERPOSER

(71) Applicant: Intel Corporation, Santa Clara, CA (US)

(72) Inventors: Juan Eduardo DOMINGUEZ, Gilbert, AZ (US); Hyoung Il KIM, Folsom, CA (US)

(21) Appl. No.: 16/323,503

(22) PCT Filed: Sep. 30, 2016
(86) PCT No.: PCT/US2016/054958

§ 371 Date: Feb. 5, 2019

(51) Int. Cl. H01L 23/538; H01L 25/18; H01L 25/00; H01L 21/48

(52) U.S. Cl. CPC H01L 23/5389; H01L 23/5385; H01L 23/5384; H01L 23/5386; H01L 23/427; H01L 25/50; H01L 21/4857; H01L 21/486; H01L 25/18

(57) ABSTRACT

Semiconductor packages including active package substrates are described. In an example, the active package substrate includes an active die and an interposer embedded within a substrate laminate. The active die may be mounted on the interposer, and die pads of the active die may be electrically connected to a first contact array of the interposer. Accordingly, signal routing of the interposer may fan out an electrical signal from the embedded die pads to several vias in the substrate laminate. One or more memory dies of a memory stack may be mounted on substrate laminate and may be electrically connected to the vias. Accordingly, the embedded active die may control the memory stack.

### TECHNICAL FIELD

Embodiments are in the field of integrated circuit packages and, in particular, semiconductor packages including package substrates having embedded dies.

### BACKGROUND

Non-volatile memory systems, such as flash memory devices, may include several memory dies controlled by a memory controller. For example, a flash memory controller may manage data stored in the memory dies of a memory stack. As the art of non-volatile memory solutions evolves, a form factor of the memory systems is expected to decrease. More particularly, to meet the requirements for mobile and ultra-mobile markets, a z-height and an x-y area of memory devices is expected to shrink.

### BRIEF DESCRIPTION OF THE DRAWINGS

FIG. 1 illustrates a sectional view of a semiconductor package assembly, in accordance with an embodiment.

FIG. 2 illustrates a detail view taken from Detail A of FIG. 1, of an active die and an interposer embedded in an active package substrate, in accordance with an embodiment.

FIG. 3 illustrates a flowchart of a method of embedding an active die and an interposer in an active package substrate, in accordance with an embodiment.

FIGS. 4A-4D illustrate operations in a method of embedding an active die in an active package substrate, in accordance with an embodiment.

FIG. 5 is a schematic of a computer system, in accordance with an embodiment.

### DESCRIPTION OF EMBODIMENTS

Semiconductor packages including active package substrates are described. In the following description, numerous specific details are set forth, such as packaging and interconnect architectures, in order to provide a thorough understanding of embodiments of the present invention. It will be apparent to one skilled in the art that embodiments of the present invention may be practiced without these specific details. In other instances, well-known features, such as specific semiconductor fabrication processes, are not described in detail in order to not unnecessarily obscure embodiments of the present invention. Furthermore, it is to be understood that the various embodiments shown in the Figures are illustrative representations and are not necessarily drawn to scale.

Meeting the space constraints of next-generation memory solutions presents a challenge. In particular, as more dies are added to a memory stack, including more memory dies and/or memory controller dies, a z-height of the device may increase and z-height limitations may be exceeded. To remain within z-height constraints, dies may be spread out laterally, but doing so could increase a footprint of the device beyond customer needs. Dies may be embedded in a package substrate to utilize the substrate envelope, but a pitch size of the embedded die pads may be closely packed, leading to a mismatch and disconnects between the die pads and substrate signal routing, e.g., vias.

In an aspect, a memory system is miniaturized by embedding one or more dies within a substrate of the system. For example, an active die, such as a memory controller, may be embedded in a package substrate to utilize available vertical height of the substrate and minimize a z-height of the memory device. Furthermore, to avoid disconnects between substrate signal routing and die pads on the embedded die, the die may be mounted on an interposer. That is, the die and the interposer may be embedded, and the interposer may fan out signals from the closely packed die pads to more widely spaced vias. Memory dies may be connected to the vias. For example, interconnect wires of the memory dies may be attached to pads on the via. Thus, the active die may be reliably connected to memory dies mounted on the package substrate to meet advanced memory system application needs.

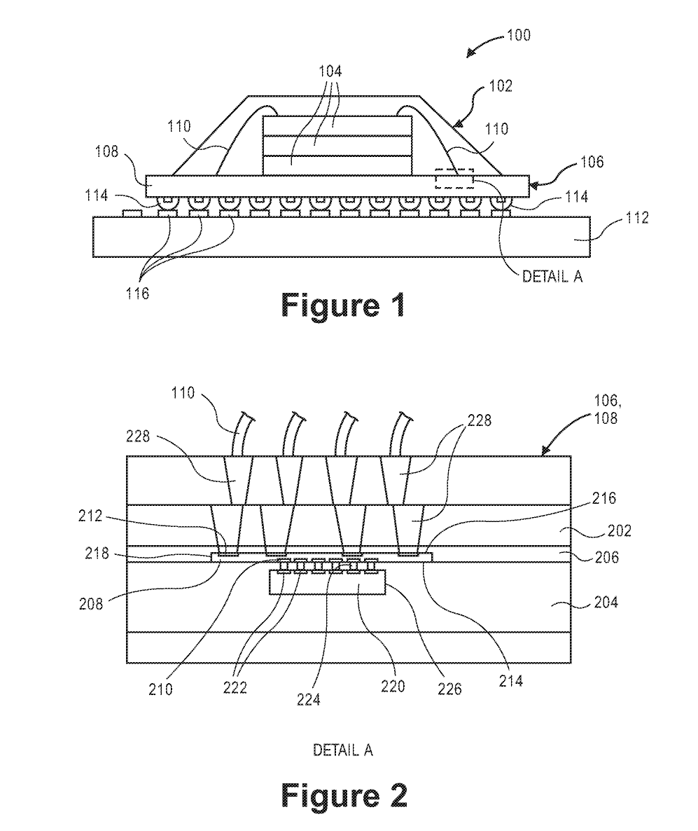

Referring to FIG. 1, a sectional view of a semiconductor package assembly is illustrated in accordance with an embodiment. A semiconductor package assembly 100 may include one or more semiconductor packages 102 having integrated dies in communication with each other. In an embodiment, semiconductor package 102 is a memory system having one or more memory dies 104 mounted on an active package substrate 106. Active package substrate 106 may be so-termed because it may include one or more active dies, e.g., logic dies, embedded in a substrate laminate 108 as described below. For example, memory dies 104 may include solid-state non-volatile computer storage media, e.g., flash memory, and the embedded active die of active package substrate 106 may be a flash memory controller. Memory die(s) 104 may be electrically connected to other memory die(s) 104, and to conductive components of active package substrate 106, by electrical interconnects 110. Electrical interconnects 110 may be, for example, wire bonds or electrical bump interconnects.

In an embodiment, active package substrate 106 may be mounted on a circuit board 112. For example, semiconductor package 102 of semiconductor package assembly 100 may be ball grid array (BGA) component having several solder balls 114 arranged in a ball field. That is, an array of solder balls 114 may be arranged in a grid or other pattern. Each solder ball 114 may be mounted and attached to a corresponding contact pad 116 of circuit board 112. Circuit board 112 may be a motherboard or another printed circuit board of a computer system or device, e.g., a flash memory stick. Circuit board 112 may include signal routing to external device connectors (not shown). Accordingly, the solder ball and contact pad attachments may provide a physical and electrical interface between the dies of semiconductor package 102 and an external device.

Referring to FIG. 2, a detail view taken from Detail A of FIG. 1, of an active die and an interposer embedded in an active package substrate is shown in accordance with an embodiment. Substrate laminate 108 of active package substrate 106 may include several layers of dielectric materials. For example, substrate laminate 108 may include a first substrate layer 202 physically connected to a second substrate layer 204 by a core layer 206. More particularly, core layer 206 may be between first substrate layer 202 and second substrate layer 204. The various layers of substrate laminate 108 may be formed from any conventional package substrate material, e.g., known organic substrate materials. In an embodiment, core layer 206 is a layer of epoxy. Similarly, core layer 206 may include composite fibers, e.g., glass or para-aramid fibers, pre-impregnated with an epoxy material, i.e., core layer 206 may include a “prepreg” material. In any case, core layer 206 may be used to laminate first substrate layer 202 onto second substrate layer 204.

In an embodiment, active package substrate 106 includes an interposer 208. Interposer 208 may be embedded within any of the various layers of substrate laminate 108. For example, interposer 208 may be disposed within core layer 206. Interposer 208 may provide an electrical interface to fan out electrical signals from a first contact array 210 on a first side of interposer 208 to a second contact array 212 on a second side of interposer 208. More particularly, first contact array 210 may be on a mounting surface 214 of interposer 208 facing second substrate layer 204, and second contact array 212 may be on an interconnect surface 216 of interposer 208 facing first substrate layer 202. Each array may include several electrical contacts, and each contact of first contact array 210 may be electrically connected to a respective contact of second contact array 212 by one or more signal lines or vias (not shown). Thus, first contact array 210 may be electrically connected to second contact array 212.

Interposer 208 may be embedded within core layer 206. More particularly, core layer 206 may surround an interposer perimeter 218 of interposer 208. In an embodiment, an epoxy material of core layer 206 may be flowed around interposer 208 to surround interposer perimeter 218. Alternatively, a cavity may be formed in core layer 206, and interposer 208 may be mounted within the cavity. In either case, a portion of core layer 206 may cover interconnect surface 216 of interposer 208. Accordingly, core layer 206 may be disposed over second contact array 212 on interconnect surface 216 of interposer 208.

The embedded interposer 208 may fan out electrical signals from first contact array 210 to second contact array 212. For example, first contact array 210 may have a first array pitch, i.e., a distance between adjacent contacts, and second contact array 212 may have a second array pitch different than the first array pitch. In an embodiment, the first array pitch is smaller than the second array pitch. The contacts of first contact array 210 may be electrically connected to the contacts of second contact array 212 by one or more signal lines or vias passing through a thickness of interposer 208. Accordingly, interposer 208 may redistribute signals from a smaller and/or tighter pitch at first contact array 210 to a larger and/or wider pitch at second contact array 212.

An active die 220 may be embedded within substrate laminate 108 to communicate electrical signals to the contacts of interposer 208 for redistribution to memory dies 104 mounted on substrate laminate 108. More particularly, active die 220 may be mounted on mounting surface 214 of interposer 208 between first substrate layer 202 and second substrate layer 204 and may include several die pads 222 electrically connected to first contact array 210 of interposer 208. For example, die pads 222 of active die 220 may be bonded to contacts of interposer 208 using state-of-the-art flip chip techniques, e.g., mass reflow, thermal bonding, etc. One or more conductive pads 224 may be located between die pads 222 and first contact array 210, and conductive pads 224 may be reflowed to attach active die 220 to interposer 208. Alternatively, die pads 222 may be bonded to contacts of interposer 208 using a low temperature solder during a lamination process. Similarly, the bond between die pads 222 and contacts of interposer 208 may be formed by applying heat directly to die pads 222 and contacts of interposer 208, e.g., using resistive heating or similar techniques. In any case, active die 220 may be bonded to interposer 208 before or after embedding interposer 208 within substrate laminate 108.

Active die 220 may be embedded within any of the various layers of substrate laminate 108. For example, second substrate layer 204 may surround a die perimeter 226 of active die 220. In an embodiment, second substrate layer 204 may be flowed around active die 220. Alternatively, second substrate layer 204 may be laminated over active die 220 after active die 220 is mounted on interposer 208. In either case, second substrate layer 204 may cover both active die 220 and a portion of interposer 208. Accordingly, the assembly of interposer 208 and active die 220 may be sandwiched between second substrate layer 204 and first substrate layer 202.

Active die 220 may be a memory controller die, e.g., a flash memory controller. Thus, die pads 222 of active die 220 may communicate with memory dies 104 to read, write, and erase data to the non-volatile memory dies 104. That is, active die 220 may be a controller for managing the logic of a flash drive. In other embodiments, however, active die 220 may be a central processing unit, or another die type.

Die pads 222 of active die 220 may be placed in communication with electrical interconnects 110 of memory die 104 through one or more electrical interconnects. Substrate laminate 108 may include several vias 228 extending through first substrate layer 202. Vias 228 may electrically connect to contacts of second contact array 212. Electrical interconnects 110 of memory die 104 may be connected to vias 228. For example, wire interconnects of memory die 104 may be bonded or attached to pads on vias 228. Accordingly, electrical interconnects 110 of memory die 104 may be electrically connected to second contact array 212. That is, vias 228 may carry an electrical signal between the embedded interposer 208 and electrical interconnects 110 of memory die 104.

Certain advantages of the structure of package assembly having active package substrate 106 should now be apparent. For example, package assembly 100 having an embedded active die 220 may have a reduced z-height as compared to a similar package assembly having a memory controller located above the package substrate and within the memory stack. Furthermore, embedded interposer 208 can redistribute electrical signals from closely spaced die pads 222 of the embedded die 220 to more widely spaced vias connected to electrical interconnects 110 of memory dies 104. Thus, reliable electrical connections may be made between memory die 104 and the embedded active die 220. Certain advantages of such a structure will also become more apparent in the context of a manufacturing method used to build active package substrate 106, as described below.

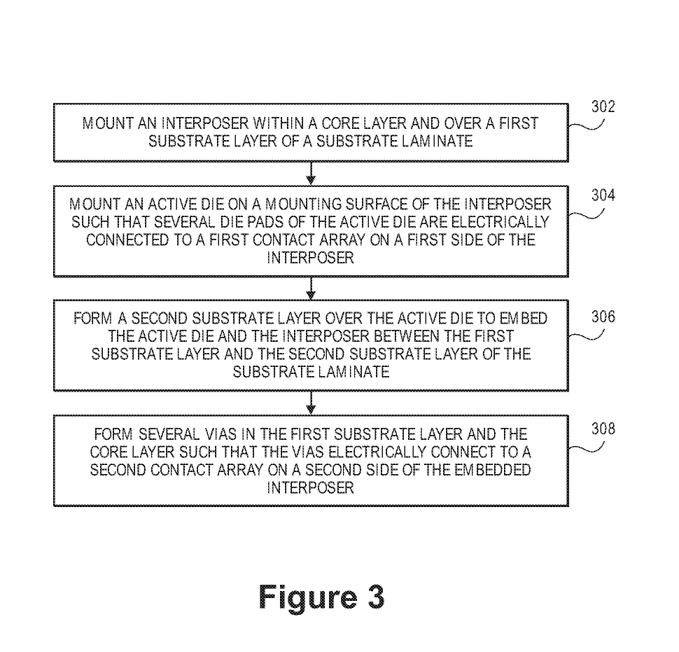

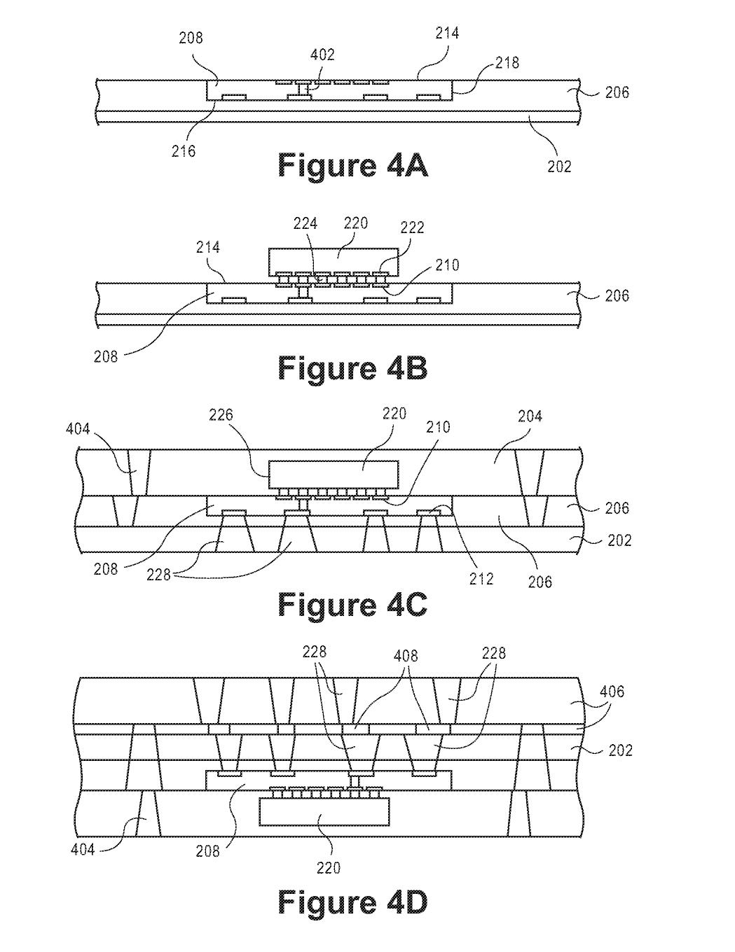

Referring to FIG. 3, a flowchart of a method of embedding an active die and an interposer in an active package substrate is shown in accordance with an embodiment. FIGS. 4A-4D illustrate operations in the method of FIG. 3. Accordingly, FIGS. 3 and 4A-4D are described in combination below.

At operation 302, interposer 208 may be mounted within core layer 206. Referring to FIG. 4A, in an embodiment, interposer 208 may be formed from a thin sheet of silicon or organic substrate material. Interposer 208 may be placed within a cavity formed in core layer 206. For example, core layer 206 may include prepreg material having a cavity shaped to conform to interposer 208. Thus, interposer 208 may be placed into the cavity such core layer 206 conforms to, and surrounds, interposer perimeter 218.

When interposer 208 is embedded within core layer 206, interposer 208 may be simultaneously mounted over first substrate layer 202 of substrate laminate 108. That is, interconnect surface 216 may face first substrate layer 202 and be disposed above first substrate layer 202. A lower wall of core layer 206 may, however, separate interconnect surface 216 from first substrate layer 202. That is, the cavity within core layer 206 may not extend fully across the thickness of core layer 206, and thus, a thin wall of core layer 206 material may be sandwiched between interposer 208 and first substrate layer 202.

Interposer 208 may adhere to core layer 206. For example, interposer 208 may be pretreated to adhere to organic substrate materials, epoxy, prepreg, etc. When interposer 208 is formed from silicon, the silicon material may be roughened by a plasma etching process to enhance friction between interposer 208 and core layer 206. When interposer 208 is formed from an organic substrate material, the organic substrate material may be compatible with, e.g., may have a high coefficient of friction with, the epoxy or organic substrate used to form core layer 206. Accordingly, interposer 208 may be securely embedded within core layer 206.

Interposer 208 may fulfill functions other than signal redistribution. For example, interposer 208 may also redistribute heat from active die 220. That is, interposer 208 may transfer heat away from active die 220 during operation of semiconductor package 102 to maintain a temperature of active die 220 within operational temperature limits. In an embodiment, interposer 208 includes a heat pipe 402 extending from interconnect surface 216, e.g., from one or more contacts of second contact array 212, to mounting surface 214, e.g., to one or more contacts of first contact array 210. Heat pipe 402 may be formed from a heat conducting material, e.g., copper, deposited along a pathway between the opposite surfaces of interposer 208. Accordingly, heat generated by active die 220 may be transmitted from first contact array 210 through heat pipe 402 to second contact array 212. Furthermore, one or more interconnects, vias, or heat pipes may be connected to heat pipe 402 at second contact array 212 to transfer heat out of active package substrate 106. Accordingly, interposer 208 may reduce a likelihood of overheating.

Interposer 208 may also stabilize active package substrate 106. For example, interposer 208 may have a size and location within substrate laminate 108 to reduce warpage of the substrate laminate. In an embodiment, interposer 208 may be located such that variations in a coefficient of thermal expansion across substrate laminate 108 are minimized. Accordingly, when substrate laminate 108 is subjected to heat, e.g., during operation of active die 220, substrate laminate 108 is less likely to bend under varying thermally-induced mechanical stresses.

At operation 304, active die 220 may be mounted on mounting surface 214 of interposer 208. Referring to FIG. 4B, mounting surface 214 of the embedded interposer 208 may be exposed. That is, mounting surface 214 may be facing away or outward from core layer 206. As such, first contact array 210 on mounting surface 214 may be exposed for attachment to die pads 222 of active die 220. Accordingly, the die pads 222 of active die 220 may be attached to the contacts of first contact array 210 such that the die pads 222 electrically connect to first contact array 210 on a first side of interposer 208, i.e., on the side of mounting surface 214.

Active die 220 may be mounted on interposer 208 using flip chip technologies. Accordingly, active die 220 may be bonded to interposer 208 before or after embedding within substrate laminate 108. For example, although the method is described as including attachment between active die 220 and interposer 208 after interposer 208 is embedded, active die 220 may be attached to interposer 208 and then the overall assembly may be embedded, e.g., during a substrate lamination process. Bonding may include copper reflow or other techniques. For example, die pads 222 may be bonded directly to contacts. In an embodiment, one or more conductive pads 224 may intervene between the die pads and contacts, and may facilitate bonding of die pads 222 to the contacts.

At operation 306, second substrate layer 204 may be formed over active die 220 to embed active die 220 and interposer 208 between first substrate layer 202 and second substrate layer 204. Referring to FIG. 4C, second substrate layer 204 may cover active die 220 and surround die perimeter 226. Accordingly, active package substrate 106 having embedded active die 220 and interposer 208 may be formed.

At operation 308, electrical interconnects between the embedded die 220 and interposer 208 may be formed to facilitate electrical communication between the embedded components and external components. Still referring to FIG. 4C, one or more vias 228 may be drilled and copper plated to electrically connect second contact array 212 to electrical interconnects 110 of memory dies 104. For example, vias 228 may be formed in first substrate layer 202 and core layer 206 to electrically connect second contact array 212 to electrical interconnects 110 of memory dies 104. Similarly, circuit board vias 404 may be drilled and copper plated from a bottom side of substrate laminate 108. Circuit board vias 404 may be electrically connected to active die 220 through respective signal routing, and thus, active die 220 may be placed in electrical communication with circuit board 112 when circuit board 112 is attached to circuit board vias 404 through solder balls 114 (FIG. 1).

Referring to FIG. 4D, additional substrate layers may be added. For example, one or more signal routing layers 406 may be built above first substrate layer 202. Signal routing layers 406 may include organic substrates, electrical signal lines, e.g., copper interconnects 408, and vias 228 to route electrical signals through active package substrate 106. It will be understood that any of the substrate laminate 108 components, e.g., substrate layers and electrical interconnects, may be formed using known substrate technologies.

Active package substrate 106 as shown in FIG. 4D has been flipped relative to the orientation shown in FIG. 4C. A top side of active package substrate 106 may be oriented upward to receive one or more memory dies 104. More particularly, electrical interconnects 110 of memory die 104 may be attached to vias 228 of active package substrate 106. Similarly, circuit board vias 404 may be connected to circuit board 112 through solder balls 114. Accordingly, a memory system having an active package substrate 106 may be formed. The memory system may include a small form factor. Furthermore, interposer 208 may be used to fan out electrical signals from the embedded active die 220, and thus, electrical interconnections of the compact memory system may be reliable and inexpensive to manufacture.

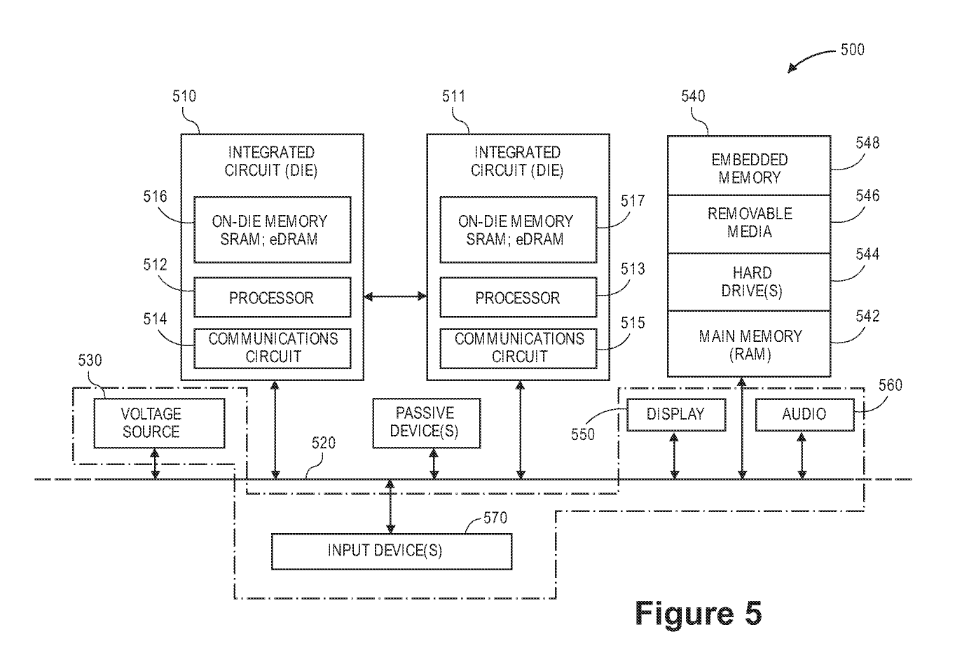

FIG. 5 is a schematic of a computer system, in accordance with an embodiment. The computer system 500 (also referred to as the electronic system 500) as depicted can embody a semiconductor package including an active package substrate, according to any of the several disclosed embodiments and their equivalents as set forth in this disclosure. The computer system 500 may be a mobile device such as a netbook computer. The computer system 500 may be a mobile device such as a wireless smart phone. The computer system 500 may be a desktop computer. The computer system 500 may be a hand-held reader. The computer system 500 may be a server system. The computer system 500 may be a supercomputer or high-performance computing system.

In an embodiment, the electronic system 500 is a computer system that includes a system bus 520 to electrically couple the various components of the electronic system 500. The system bus 520 is a single bus or any combination of busses according to various embodiments. The electronic system 500 includes a voltage source 530 that provides power to the integrated circuit 510. In some embodiments, the voltage source 530 supplies current to the integrated circuit 510 through the system bus 520.

The integrated circuit 510 is electrically coupled to the system bus 520 and includes any circuit, or combination of circuits according to an embodiment. In an embodiment, the integrated circuit 510 includes a processor 512 that can be of any type. As used herein, the processor 512 may mean any type of circuit such as, but not limited to, a microprocessor, a microcontroller, a graphics processor, a digital signal processor, or another processor. In an embodiment, the processor 512 includes, or is coupled with, a semiconductor package including an active package substrate, as disclosed herein. In an embodiment, SRAM embodiments are found in memory caches of the processor. Other types of circuits that can be included in the integrated circuit 510 are a custom circuit or an application-specific integrated circuit (ASIC), such as a communications circuit 514 for use in wireless devices such as cellular telephones, smart phones, pagers, portable computers, two-way radios, and similar electronic systems, or a communications circuit for servers. In an embodiment, the integrated circuit 510 includes on-die memory 516 such as static random-access memory (SRAM). In an embodiment, the integrated circuit 510 includes embedded on-die memory 516 such as embedded dynamic random-access memory (eDRAM).

In an embodiment, the integrated circuit 510 is complemented with a subsequent integrated circuit 511. Useful embodiments include a dual processor 513 and a dual communications circuit 515 and dual on-die memory 517 such as SRAM. In an embodiment, the dual integrated circuit 511 includes embedded on-die memory 517 such as eDRAM.

In an embodiment, the electronic system 500 also includes an external memory 540 that in turn may include one or more memory elements suitable to the particular application, such as a main memory 542 in the form of RAM, one or more hard drives 544, and/or one or more drives that handle removable media 546, such as diskettes, compact disks (CDs), digital variable disks (DVDs), flash memory drives, and other removable media known in the art. The external memory 540 may also be embedded memory 548 such as the first die in a die stack, according to an embodiment.

In an embodiment, the electronic system 500 also includes a display device 550, and an audio output 560. In an embodiment, the electronic system 500 includes an input device such as a controller 570 that may be a keyboard, mouse, trackball, game controller, microphone, voice-recognition device, or any other input device that inputs information into the electronic system 500. In an embodiment, an input device 570 is a camera. In an embodiment, an input device 570 is a digital sound recorder. In an embodiment, an input device 570 is a camera and a digital sound recorder.

As shown herein, the integrated circuit 510 can be implemented in a number of different embodiments, including a semiconductor package including an active package substrate, according to any of the several disclosed embodiments and their equivalents, an electronic system, a computer system, one or more methods of fabricating an integrated circuit, and one or more methods of fabricating an electronic assembly that includes a semiconductor package including an active package substrate, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a semiconductor package including an active package substrate embodiments and their equivalents. A foundation substrate may be included, as represented by the dashed line of FIG. 5. Passive devices may also be included, as is also depicted in FIG. 5.

Embodiments of a semiconductor package including an active package substrate are described above. In an embodiment, an active package substrate includes a substrate laminate including a core layer between a first substrate layer and a second substrate layer. The active package substrate include an interposer within the core layer. The interposer includes a first contact array on a mounting surface and a second contact array on an interconnect surface. The first contact array is electrically connected to the second contact array. The active package substrate includes an active die within the substrate laminate. The active die is mounted on the mounting surface of the interposer. The active die includes several die pads electrically connected to the first contact array.

In one embodiment, the substrate laminate includes several vias extending through the first substrate layer and electrically connected to the second contact array.

In one embodiment, a first array pitch of the first contact array is smaller than a second array pitch of the second contact array.

In one embodiment, the second substrate layer surrounds a die perimeter of the active die.

In one embodiment, the core layer surrounds an interposer perimeter of the interposer and covers the interconnect surface of the interposer.

In one embodiment, the active package substrate includes one or more conductive pads between the die pads and the first contact array.

In one embodiment, the interposer includes a heat pipe extending from the interconnect surface to the mounting surface.

In an embodiment, a semiconductor package includes an active package substrate including a substrate laminate including a core layer between a first substrate layer and a second substrate layer. The active package substrate includes an interposer within the core layer. The interposer includes a first contact array on a mounting surface and a second contact array on an interconnect surface. The first contact array is electrically connected to the second contact array. The active package substrate includes an active die within the substrate laminate. The active die is mounted on the mounting surface of the interposer. The active die includes several die pads electrically connected to the first contact array. The semiconductor package includes a memory die mounted on the substrate laminate. The memory die includes several electrical interconnects electrically connected to the second contact array.

In one embodiment, the substrate laminate includes several vias extending through the first substrate layer and electrically connected to the second contact array. The electrical interconnects are connected to the several vias.

In one embodiment, a first array pitch of the first contact array is smaller than a second array pitch of the second contact array.

In one embodiment, the second substrate layer surrounds a die perimeter of the active die.

In one embodiment, the core layer surrounds an interposer perimeter of the interposer and covers the interconnect surface of the interposer.

In one embodiment, the semiconductor package includes one or more conductive pads between the die pads and the first contact array.

In one embodiment, the interposer includes a heat pipe extending from the interconnect surface to the mounting surface.

In an embodiment, a method of embedding an active die and an interposer in an active package substrate includes mounting an interposer within a core layer and over a first substrate layer of a substrate laminate. The interposer includes a first contact array on a mounting surface and a second contact array on an interconnect surface facing the first substrate layer. The method includes mounting an active die on the mounting surface of the interposer. The active die includes several die pads electrically connected to the first contact array. The method includes forming a second substrate layer over the active die to embed the active die and the core layer between the first substrate layer and the second substrate layer of the substrate laminate.

In one embodiment, the method includes forming several vias in the first substrate layer and the core layer. The several vias are electrically connected to the second contact array of the interposer.

In one embodiment, a first array pitch of the first contact array is smaller than a second array pitch of the second contact array.

In one embodiment, the method includes mounting a memory die on the substrate laminate. The memory die includes several electrical interconnects electrically connected to several vias.

In one embodiment, the second substrate layer surrounds a die perimeter of the active die.

In one embodiment, the core layer surrounds an interposer perimeter of the interposer and covers the interconnect surface of the interposer.

What is claimed is:

1. An active package substrate, comprising:
a substrate laminate including a core layer between a first substrate layer and a second substrate layer;
an interposer within the core layer, wherein the interposer includes a first contact array on a mounting surface and a second contact array on an interconnect surface, and wherein the first contact array is electrically connected to the second contact array; and
an active die within the substrate laminate, wherein the active die is mounted on the mounting surface of the interposer, and wherein the active die includes a plurality of die pads electrically connected to the first contact array.

2. The active package substrate of claim 1, wherein the substrate laminate includes a plurality of vias extending through the first substrate layer and electrically connected to the second contact array.

3. The active package substrate of claim 2, wherein a first array pitch of the first contact array is smaller than a second array pitch of the second contact array.

4. The active package substrate of claim 3, wherein the second substrate layer surrounds a die perimeter of the active die.

5. The active package substrate of claim 3, wherein the core layer surrounds an interposer perimeter of the interposer and covers the interconnect surface of the interposer.

6. The active package substrate of claim 1 further comprising one or more conductive pads between the die pads and the first contact array.

7. The active package substrate of claim 1, wherein the interposer includes a heat pipe extending from the interconnect surface to the mounting surface.

8. A semiconductor package, comprising:
an active package substrate including
a substrate laminate including a core layer between a first substrate layer and a second substrate layer,
an interposer within the core layer, wherein the interposer includes a first contact array on a mounting surface and a second contact array on an interconnect surface, and wherein the first contact array is electrically connected to the second contact array, and
an active die within the substrate laminate, wherein the active die is mounted on the mounting surface of the interposer, and wherein the active die includes a plurality of die pads electrically connected to the first contact array; and
a memory die mounted on the substrate laminate, wherein the memory die includes a plurality of electrical interconnects electrically connected to the second contact array.

9. The semiconductor package of claim 8, wherein the substrate laminate includes a plurality of vias extending through the first substrate layer and electrically connected to the second contact array, and wherein the electrical interconnects are connected to the plurality of vias.

10. The semiconductor package of claim 9, wherein a first array pitch of the first contact array is smaller than a second array pitch of the second contact array.

11. The semiconductor package of claim 10, wherein the second substrate layer surrounds a die perimeter of the active die.

12. The semiconductor package of claim 10, wherein the core layer surrounds an interposer perimeter of the interposer and covers the interconnect surface of the interposer.

13. The semiconductor package of claim 8 further comprising one or more conductive pads between the die pads and the first contact array.

14. The semiconductor package of claim 8, wherein the interposer includes a heat pipe extending from the interconnect surface to the mounting surface.

15. A method, comprising:
mounting an interposer within a core layer and over a first substrate layer of a substrate laminate, wherein the interposer includes a first contact array on a mounting surface and a second contact array on an interconnect surface facing the first substrate layer;
mounting an active die on the mounting surface of the interposer, wherein the active die includes a plurality of die pads electrically connected to the first contact array; and
forming a second substrate layer over the active die to embed the active die and the core layer between the first substrate layer and the second substrate layer of the substrate laminate.

16. The method of claim 15 further comprising forming a plurality of vias in the first substrate layer and the core layer, wherein the plurality of vias are electrically connected to the second contact array of the interposer.

17. The method of claim 16, wherein a first array pitch of the first contact array is smaller than a second array pitch of the second contact array.

18. The method of claim 17 further comprising mounting a memory die on the substrate laminate, wherein the memory die includes a plurality of electrical interconnects electrically connected to the plurality of vias.

19. The method of claim 18, wherein the second substrate layer surrounds a die perimeter of the active die.

20. The method of claim 18, wherein the core layer surrounds an interposer perimeter of the interposer and covers the interconnect surface of the interposer.
